(19) United States
(12) Patent Application Publication
(10) Pub. No.: US 2011/0096511 A1
(43) Pub. Date: Apr. 28, 2011

(54) Ultra-low profile multi-chip module

(75) Inventors: Christian Krutzik, Costa Mesa, CA (US); Sambo He, Riverside, CA (US)

(73) Assignees: Christian Krutzik; Sambo He; Irvine Sensors Corporation

(21) Appl. No.: 12/925,620

(22) Filed: Oct. 25, 2010

Related U.S. Application Data
(60) Provisional application No. 61/279,778, filed on Oct. 26, 2009.

(51) Int. Cl. H05K 7/00

(52) U.S. Cl. 361/728

(57) ABSTRACT

The disclosed invention comprises a substrate having one or more conductive metal traces comprising one or more electrical access leads terminating on a lateral surface of the substrate.

A layer or stack of layers comprising one or more integrated circuit chips having one or more access leads in electrical connection with one or more integrated circuit bond pads on the one or more integrated circuit chips is bonded to the substrate. The surface area of the layers is less than the surface area of the substrate so as to define one or more component surface areas on the substrate. The access leads of the layers are oriented to be substantially coplanar and in vertical registration with the access leads of the substrate access leads.

One or more T-connect structures between the respective access leads of the substrate and layers are defined using metalized traces for the interconnection of the integrated circuit bond pads in the layers to predetermined access leads of the substrate and/or the respective other layers.

The conductive traces of the substrate are in electrical connection with the component surface area for providing one or more discrete electrical components in electrical connection with the layers in the stack to define a low-profile electronic module without the need for a top or bottom cap chip in the layer.

### BACKGROUND OF THE INVENTION

1. Field of the Invention

The invention relates generally to the field of electronic circuits and modules.

More specifically, the invention relates to a high-density, low-profile module comprising one or more integrated circuit chips which, in one embodiment, comprises a stack of integrated circuit chips.

2. Description of the Related Art

The invention relates to the fabrication of three-dimensional electronic packages in which a plurality of individual integrated circuit (IC) chips are secured together in a stack which provides a very high density electronic package.

As stated in common assignee U.S. Pat. No. 5,279,991, issued Jan. 18, 1994, which provides more detailed disclosure of certain process steps, the assignee of this application pioneered the use of IC chip stacks, first as modules providing photo-detector focal plane circuitry and then as units suitable for computer memories and the like. For instance, U.S. Pat. Nos. 4,525,921 and 4,646,128 relate to stacks designed for general use as memory devices and other non-focal-plane packages.

The methods used for fabricating such three-dimensional (3D) IC chip stacks have become increasingly sophisticated. The three-dimensional approach has been applied to both SRAM and DRAM memory chips with satisfactory results. In addition to memory chips, various other types of IC chips may be stacked in 3-D packages.

A difficulty associated with stacks used as memory devices and also with other non-focal-plane packages is the difficulty of connecting exterior circuitry to the large number of conductors on the access plane of the completed stack.

Focal plane chip stack modules may incorporate multiplexer circuitry to address this problem which greatly reduces the number of module output connections. However, providing output connections for memory devices and other non-multiplexed devices is a much greater challenge.

Stacked microelectronic modules comprised of layers containing integrated circuitry are desirable in that three-dimensional structures provide increased circuit density per unit area. The elements in a three-dimensional module are typically arranged in a stacked configuration and may comprise stacked integrated circuit die, stacked prepackaged integrated circuit packages, stacked modified prepackaged integrated circuits or stacked neo-layers such as disclosed in the various U.S. patents cited herein.

There are two acknowledged orientations which represent the structural relationship of the stacked IC chips in a module to the underling substrate (e.g. a multi-layer printed circuit board or flex circuit fabricated from FR-4 or polyimide glass material), which makes outside electrical circuitry available for connection to the multiplicity of electrical leads (terminals) which are formed on the access plane face of the stacked module and which lead to the IC circuitry embedded in the module. The two most common structures are described as a “sliced bread” stack and as a “pancake” stack.

The patents cited herein disclose devices and methods wherein layers containing integrated circuit chips are stacked and electrically interconnected using any number of stacking techniques. For example, Irvine Sensors Corporation, assignee of the instant application, has developed several patented techniques for stacking and interconnecting multiple integrated circuits in the form of prepackaged integrated circuit chips, modified prepackaged integrated circuit chips, modified bare integrated circuit chips and neolayers comprising encapsulated integrated circuit chips having one or more bond pads electrically rerouted to a predetermined location on the layer (such as the perimeter or edge of the layer) to define an electrical access lead. Some of these techniques are disclosed in U.S. Pat. Nos. 4,525,921; 4,551,629; 4,646,128; 4,706,166; 5,104,820; 5,347,428; 5,432,729; 5,688,721; 5,953,588; 6,117,704; 6,560,109; 6,706,971; 6,717,061; 6,734,370; 6,806,559 and U.S. Pub. No. 2006/0087883.

Generally speaking, in a three-dimensional module, layers containing integrated circuits are bonded together one on top of another in a stack so as to maintain a surface area or “footprint” approximately equivalent to that of the largest layer in the stack. The input/output bond pad connections of the various integrated circuit die in the layers are electrically rerouted to a lateral surface of the stacked module or to conductive area interconnects or to electrically conductive vias defined at one or more predetermined locations in the stack.

A common method of electrically interconnecting the layers comprises electrically rerouting the input/output connections to the edges of the layers to define one or more layer access leads. Conductive “T-connect” structures for interconnecting one or more layers by means of connecting the one or more access leads, are defined on the lateral surfaces of the stack of layers. These IC input/output connections are electrically interconnected using metalized, conductive bus structures on the sides of the stack using photolithographic and conductive plating processes to create T-connects using techniques such as those described in the patents identified.

Another method for interconnecting layers in a stack comprises the use of electrically conductive vias that are defined at predetermined locations in the stack and used to electrically interconnect one or more layers in a stack.

As stated above, in one stack orientation, the layers of the module extend in planes perpendicular to the plane of the substrate. In the alternative orientation, the layers of the module extend in planes parallel to the plane of the substrate.

The substrates may be located below, above, or along the side of the stacked chip module. Common assignee U.S. Pat. No. 4,706,166 discloses a “sliced bread” stack in which the IC chips in the stacked module are in planes perpendicular to the stack-supporting substrate. The substrate carries electrical conductors which lead to external circuitry. The access plane of the stack faces the supporting substrate and the electrical connections between the stack and the face of the substrate are formed by bonding aligned solder bumps on the abutting surfaces; a process analogous to surface mount technology. In such an orientation, the lead-out terminals, also referred to herein as access leads, are necessarily located very close to one another, a fact which creates difficulties in obtaining satisfactory lead-out connections.

“Pancake” stacks comprise IC chips which are in planes parallel to a supporting substrate. The electrical access leads from the many terminals on the access plane of the stack are preferably brought either to the bottom or to the top of the stack as disclosed in, for instance, U.S. Pat. No. 5,279,991.

“Pancake” stacks, as distinguished from “sliced bread” stacks, are more likely to be used where a smaller number of IC chips are included in the stacked layer module, either because fewer chips are needed for a particular module or because of limited “headroom”, i.e., limited available vertical space in which the module is located.

The present invention deals primarily with the problem of connecting the circuitry of IC chips in pancake stacks with suitable access leads which are used for connection to external circuitry and which also optimizes such electrical connections for use in high-speed circuitry.

### BRIEF SUMMARY OF THE INVENTION

The present invention addresses the foregoing needs by providing an ultra-low profile module without the need for a cap/rerouting chip. Significant innovations of the invention can be implemented using a single layer or multilayer module. The invention uses different combinations and variations of these embodiments as well as others described in the detailed description to provide an innovative low-profile electronic module.

Prior art methods and devices using layers oriented parallel to the substrate utilize a cap chip layer which is an integral part of the stack and which provides means for interconnecting the circuitry inside the stack with exterior circuitry. This has the undesirable result of adding vertical height to the module. The invention herein avoids the foregoing deficiencies and further provides for the reduction in electrical parasitics that adversely effect circuit performance at high frequencies. Parastics from typical packaging structure such as vias, additional trace length, impedance discontinuities, etc. are all greatly minimized by the invention.

The disclosed device comprises a substrate having one or more conductive metal traces comprising one or more electrical access leads terminating on a lateral surface of the substrate. A layer or stack of layers comprising one or more integrated circuit chips having one or more access leads in electrical connection with one or more bond pads on the one or more integrated circuit chips, is bonded to the substrate. The surface area of the layers is less than the surface area of the substrate so as to define one or more component surface areas on the substrate. The access leads of the layers are oriented to be substantially coplanar with the access leads of the substrate access leads.

One or more T-connect structures between the respective coplanar access leads of the substrate and layers are defined using metalized traces for the interconnection of the bond pads in layers to predetermined access leads of the substrate and/or the respective other layers.

The invention achieves minimal interconnect length to the substrate to optimize high-frequency interconnections. Furthermore, standard design techniques can be applied to the bus structure of the invention to control impedances and to provide capacitive/inductive matching to T-connects by permitting tuning of the bus structures. State-of-the art simulation tools easily optimize these structures. Furthermore, bus traces from the stack can be directly routed and configured into stripline or micro-stripline (controlled impedance) structures in the substrate with minimal discontinuities to achieve a target impedance. The same art can be applied to optimize power/ground connections to eliminate undesirable inductance. Electrical layers of the stack may optionally contain capacitors to provide high-frequency decoupling to eliminate additional parasitics introduced by interconnects to the substrate.

The conductive traces of the substrate are in electrical connection with the component surface area or areas for providing one or more discrete electrical components in electrical connection with the layers in the stack to define a low-profile electronic module without the need for a top or bottom cap chip in the layer.

While the claimed apparatus and method herein has or will be described for the sake of grammatical fluidity with functional explanations, it is to be understood that the claims, unless expressly formulated under 35 USC 112 are not to be construed as necessarily limited in any way by the construction of “means” or “steps” limitations, but are to be accorded the full scope of the meaning and equivalents of the definition provided by the claims under the judicial doctrine of equivalents and, in the case where the claims are expressly formulated under 35 USC 112, are to be accorded full statutory equivalents under 35 USC 112.

### BRIEF DESCRIPTION OF THE SEVERAL VIEWS OF THE DRAWINGS

FIG. 1 depicts a perspective view of a preferred embodiment of the module of the invention.

FIG. 2 depicts a cross-section of the stack of layers of the module in FIG. 1 of the invention in a “stack of pancakes” orientation.

FIG. 2A depicts a cross-section of a T-connect of the invention.

FIG. 3 is a view of the lateral surface of the module of FIG. 1 of the invention showing the access leads of the layers and the substrate in electrical communication by means of T-connects in the form of conductive traces.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

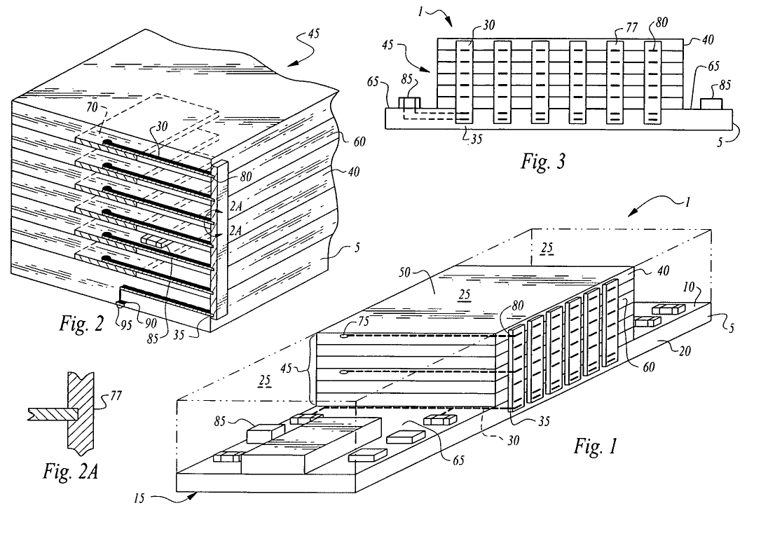

Turning now to the figures wherein like numerals depict like elements among the several views, FIG. 1 depicts a preferred embodiment of the ultra-low profile module 1 of the invention and FIGS. 2 and 2A depict a more detailed view of the stack of IC layers of module 1 as further discussed below. FIG. 3 is a front view of the module of the invention showing the access leads from the layers in the stack and of the substrate in electrical connection by means of a conductive trace or bus in the form of a T-connect structure.

As is seen in FIGS. 1-3, module 1 comprises a substrate 5 having a first substrate surface 10, a second substrate surface 15, a substrate lateral surface 20, and a substrate surface area 25.

Substrate 5 comprises one or a plurality of electrically conductive traces 30 wherein at least one of the electrically conductive traces 30 comprises a substrate access lead 35 terminating on the substrate lateral surface 20. Electrically conductive traces 30 on the substrate or layers may be configured so as to define a stripline, micro-stripline or other controlled impedance structure and be connected to predetermined locations in the module to achieve a target impedance. Substrate 5 is preferably fabricated as a multi-layer structure such as a printed circuit board fabricated from FR-4, polyimide or similar material using known fabrication processes.

Module 1 further comprises at least one integrated circuit chip or “IC” layer 40 or a stack of IC layers 45 where at least one of layers 40 comprises a layer surface area 50 and a layer lateral surface 60.

It is noted when referring to the surface area of layer 40 herein, a stack of substantially identical-sized layers 45 has substantially the same surface area or “footprint” as that of a single layer 40 and that when the instant disclosure refers to the surface area of a layer, it is intended that the surface area of a stack of layers each having substantially the same surface area is within the definition of the surface area of one of the layers in the stack. Stated differently, the surface area of a layer and the surface area of a stack of layers are used interchangeably herein to define the area occupied by the layer or stack of layers.

Integrated circuit layer 40 may comprise any stackable layer containing one or more integrated circuit chips, including but not limited to one or a stack of modified or bare integrated circuit die, one or a stack of prepackaged integrated circuit chips, one or a stack of modified prepackaged parts, one or a stack of neolayers, one or a stack of layers with a predetermined electronic function such as a silicon capacitor or one or more discrete electronic components in the layer or a combination of the foregoing stackable layers as are described in the above-referenced patents and applications.

Layers 40 comprising the stack of layers 45 define a layer surface area 50 less than that of the substrate surface area. Layer 40 or stack of layers 45 are bonded to substrate 5 so that substrate lateral surface 20 is substantially coplanar with layer lateral surface 60 and whereby one or more component surface areas 65 on first substrate surface 10 are defined.

Layer 40 comprises an integrated circuit chip 70 having at least one integrated chip bond pad 75 in electrical communication with an integrated circuit chip access lead 80 terminating on layer lateral surface 60.

Substrate access lead 35 is in electrical communication with layer access lead 80 such as by means of an electrically conductive trace 30.

One or more electrically conductive traces 30 are defined on the coplanar lateral surfaces of the substrate and layer or stack of layers to connect predetermined access leads on the layers and the substrate define one or more conductive T-connect structures 77 thereon such as best depicted in FIG. 2A and FIG. 3. In this manner, predetermined bond pads and substrate access leads are electrically connected to each other.

Module 1 or layer 40 may further comprise at least one discrete electronic component 85 disposed on component surface area 65 that is in electrical communication with at least one bond pad 75 on the layer by means or one or more electrically conductive traces 30 in the substrate. Conductive traces 30 of substrate 5 terminate (such as in the form of a bond pad) at predetermined locations on the component surface area 65 and are in electrical connection with one or more predetermined access leads of the substrate or layer or layers.

In this manner, discrete components for support of circuitry in the layers in the stack are readily and easily provided. Discrete components 85 may include, but are not limited to, surface mounted capacitors, active semiconductor devices, resistors or inductors, bare or packaged die or equivalent devices.

Second substrate surface 15 preferably comprises at least one substrate bond pad 90 in electrical communication with at least one integrated circuit bond pad 75. Substrate bond pad 90 is preferably provided with a solder ball 95 thereon to facilitate later assembly of the module to external circuitry.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below are in a certain combination, it must be expressly understood that the invention includes other combinations of fewer, more or different elements, which are disclosed above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus, if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense, it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention.

We claim:

1. An electronic module comprising:
a substrate having a first substrate surface, a second substrate surface and a substrate lateral surface,
the substrate having a substrate surface area,
the substrate comprising a plurality of electrically conductive traces wherein at least one of the electrically conductive traces comprises a substrate access lead terminating on the substrate lateral surface,
a layer comprising a layer surface area and a layer lateral surface,
the layer surface area less than that of the substrate surface area,
the layer bonded to the substrate wherein the substrate lateral surface is substantially coplanar with the layer lateral surface and whereby a component surface area is defined,
the layer comprising an integrated circuit chip having at least one bond pad in electrical communication with an integrated circuit chip access lead terminating on the layer lateral surface,
the substrate access lead in electrical communication with the layer access lead.

2. The module of claim 1 wherein at least one discrete electronic component is disposed on the component surface area and is in electrical communication with at least one bond pad on the layer.

3. The module of claim 2 wherein the layer comprise a prepackaged integrated circuit chip.

4. The module of claim 2 wherein the layer comprises a modified prepackaged integrated circuit chip.

5. The module of claim 2 wherein the layer comprises a neolayer.

6. The module of claim 2 wherein the second substrate surface comprises at least one substrate bond pad in electrical communication with at least one electrically conductive trace.

7. An electronic module comprising:
a substrate having a first substrate surface, a second substrate surface and a substrate lateral surface,
the substrate having a substrate surface area,
the substrate comprising an electrically conductive trace comprising a substrate access lead terminating on the substrate lateral surface,
a plurality of layers defining a stack wherein at least one of the layers comprises a layer surface area and a layer lateral surface,
the layer surface area less than that of the substrate surface area,
the stack bonded to the substrate wherein the substrate lateral surface is substantially coplanar with the layer lateral surface and whereby a component surface area is defined,
the at least one layer comprising an integrated circuit chip having at least one bond pad in electrical communication with an integrated circuit chip access lead terminating on the layer lateral surface,
the substrate access lead in electrical communication with the layer access lead.

8. The module of claim 7 wherein at least one discrete electronic component is disposed on the component surface area and is in electrical communication with at least one bond pad on the layer.

9. The module of claim 8 wherein the layer comprises a prepackaged integrated circuit chip.

10. The module of claim 8 wherein the layer comprises a modified prepackaged integrated circuit chip.

11. The module of claim 8 wherein the layer comprises a neolayer.

12. The module of claim 8 wherein the second substrate surface comprises at least one substrate bond pad in electrical communication with at least one electrically conductive trace.

13. The module of claim 8 wherein the layer comprises a discrete electronic component.

14. The module of claim 8 wherein the layer comprises a decoupling capacitor.

15. The module of claim 8 wherein the substrate comprises a controlled impedance structure.
